(19) United States
(12) Patent Application Publication
(10) Pub. No.: US 2012/0146728 A1
(43) Pub. Date: Jun. 14, 2012

(54) COMPOUND SEMICONDUCTOR DEVICE AND METHOD OF MANUFACTURING THE SAME

(75) Inventors: Kozo MAKIYAMA, Kawasaki (JP); Toshihide Kikkawa, Kawasaki (JP)

(73) Assignee: FUJITSU LIMITED, Kawasaki (JP)

(21) Appl. No.: 13/278,392

(22) Filed: Oct. 21, 2011

(30) Foreign Application Priority Data
Dec. 10, 2010 (JP) 2010-276294

(51) Int. Cl. H03F 3/16; H01L 21/336; H01L 29/778

(52) U.S. Cl. 330/277; 257/194; 438/591; 257/E29.246; 257/E21.409

(57) ABSTRACT

A compound semiconductor device is provided with a compound semiconductor layer and a gate electrode formed on the compound semiconductor layer via a gate insulating film, in which the gate insulating film is one in which SiₓN_{y} is contained as an insulating material, SiₓN_{y} is 0.638≦x/y≦0.863, and a hydrogen-terminated group concentration is set to a value within a range of not less than 2×10²²/cm³ nor more than 5×10²²/cm³.

### CROSS-REFERENCE TO RELATED APPLICATIONS

This application is based upon and claims the benefit of priority of the prior Japanese Patent Application No. 2010-276294, filed on Dec. 10, 2010, the entire contents of which are incorporated herein by reference.

### FIELD

The present embodiments relate to a compound semiconductor device and a method of manufacturing the same.

### BACKGROUND

A nitride semiconductor device has been actively developed as a high withstand voltage and high output semiconductor device by utilizing its characteristics of a high saturation electron velocity, a wide band gap, and so on. As for the nitride semiconductor device, many reports on a field effect transistor, particularly a high electron mobility transistor (High Electron Mobility Transistor: HEMT) have been made. Particularly, attention has been given to an AlGaN/GaN-HEMT in which GaN is used as an electron transit layer and AlGaN is used as an electron supply layer. In the AlGaN/GaN-HEMT, distortion ascribable to a lattice constant difference between GaN and AlGaN occurs in AlGaN. By piezoelectric polarization and spontaneous polarization of AlGaN that are caused by the distortion, a high-concentration two-dimensional electron gas (2DEG) is obtained. Thus, the high withstand voltage and high output are achieved.

### Patent Document

[Patent Document 1] Japanese Laid-open Patent Publication No. 2009-76845

However, the nitride semiconductor device used in high voltage application is likely to be affected by charge traps existing in an insulating film, on the front surface of a semiconductor, in the inside of crystals, and so on of the device, and has a problem that electric properties (current-voltage property, gain property, output property, collapse, and so on) change according to its operating state.

The above-described problem will be described in detail.

The charge traps existing in the structure of the semiconductor device vary a potential distribution around the periphery of the traps by activation (electrification) by electric fields or by traps of electrons and holes. As a result, the electric properties change to thereby affect the stable operation of the semiconductor device. In an actual semiconductor device, a change in threshold voltage during its operation, a change in current amount accompanied by the above change, and a change in gain appear. As a semiconductor device having stable electric properties, it is necessary to make a mechanism in which the change in electric properties is suppressed, namely a trap phenomenon or the like is mitigated inside the device. Particularly, a reduction in the charge traps or inactivation around the periphery of a gate electrode and in a gate insulating film, where electric fields concentrate, and which are easily affected by the traps, is an important problem.

Further, it is necessary to establish a device structure in which the charge traps themselves to be the cause of the change in electric properties are reduced and a method of manufacturing the same. The existence of charge traps results in a defect in the semiconductor device, and reducing the charge traps in the semiconductor device is an imperative problem also from a point of view of long-term reliability.

### SUMMARY

An aspect of the compound semiconductor device includes: a compound semiconductor layer; and a gate electrode formed on the compound semiconductor layer via a gate insulating film, in which the gate insulating film is one in which SiₓN_{y} is contained as an insulating material, the SiₓN_{y} is 0.638≦x/y≦0.863, and a hydrogen-terminated group concentration is set to a value within a range of not less than 2×10²²/cm³ nor more than 5×10²²/cm³.

An aspect of the compound semiconductor device includes: a compound semiconductor layer; and a gate electrode formed on the compound semiconductor layer via a gate insulating film, in which the gate insulating film is one in which SiₓO_{y}Nₓ is contained as an insulating material, the SiₓO_{y}N_{z} satisfies x:y:z=0.256 to 0.384:0.240 to 0.360:0.304 to 0.456 and x+y+z=1, and a hydrogen-terminated group concentration is set to a value within a range of not less than 2×10²²/cm³ nor more than 5×10²²/cm³.

An aspect of the method of manufacturing the compound semiconductor device includes: forming a gate insulating film on a compound semiconductor layer; and forming a gate electrode on the compound semiconductor layer via the gate insulating film, in which the gate insulating film is one in which SiₓN_{y} is contained as an insulating material, the SiₓN_{y} is 0.638≦x/y≦0.863 and a hydrogen-terminated group concentration is set to a value within a range of not less than 2×10²²/cm³ nor more than 5×10²²/cm³.

An aspect of the method of manufacturing the compound semiconductor device includes: forming a gate insulating film on a compound semiconductor layer; and forming a gate electrode on the compound semiconductor layer via the gate insulating film, in which the gate insulating film is one in which SiₓO_{y}N_{z} is contained as an insulating material, the SiₓO_{y}N_{z} satisfies x:y:z=0.256 to 0.384:0.240 to 0.360:0.304 to 0.456 and x+y+z=1, and a hydrogen-terminated group concentration is set to a value within a range of not less than 2×10²²/cm³ nor more than 5×10²²/cm³.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A to FIG. 1C are schematic cross-sectional views depicting a method of manufacturing a MIS-type AlGaN/GaN-HEMT according to a first embodiment in order of processes;

FIG. 2A and FIG. 2B are schematic cross-sectional views, subsequent to FIG. 1A to FIG. 1C, depicting the method of manufacturing the MIS-type AlGaN/GaN-HEMT according to the first embodiment in order of processes;

FIG. 3A and FIG. 3B are schematic cross-sectional views, subsequent to FIG. 2A and FIG. 2B, depicting the method of manufacturing the MIS-type AlGaN/GaN-HEMT according to the first embodiment in order of processes;

FIG. 4 is a schematic view depicting a bonding state of SiN of a gate insulating film formed according to the first embodiment;

FIG. 5A to FIG. 5C are characteristic charts depicting results of various experiments for confirming a good application range of a hydrogen-terminated group concentration in SiN in the first embodiment;

FIG. 6A and FIG. 6B are characteristic charts depicting results of various experiments for confirming a good application range of an interatomic hydrogen concentration in SiN in the first embodiment;

FIG. 7A to FIG. 7C are schematic cross-sectional views depicting main processes of a MIS-type AlGaN/GaN-HEMT according to a modified example 1 of the first embodiment;

FIG. 8A to FIG. 8C are schematic cross-sectional views depicting main processes of a MIS-type AlGaN/GaN-HEMT according to a modified example 2 of the first embodiment;

FIG. 9A and FIG. 9B are schematic cross-sectional views depicting main processes of a MIS-type AlGaN/GaN-HEMT according to a modified example 3 of the first embodiment;

FIG. 10A and FIG. 10B are schematic cross-sectional views, subsequent to FIG. 9A and FIG. 9B, depicting the main processes of the MIS-type AlGaN/GaN-HEMT according to the modified example 3 of the first embodiment;

FIG. 11A and FIG. 11B are schematic cross-sectional views depicting main processes of a MIS-type AlGaN/GaN-HEMT according to a second embodiment;

FIG. 12A to FIG. 12C are schematic cross-sectional views depicting main processes of a MIS-type AlGaN/GaN-HEMT according to a modified example 1 of the second embodiment;

FIG. 13A to FIG. 13C are schematic cross-sectional views depicting main processes of a MIS-type AlGaN/GaN-HEMT according to a modified example 2 of the second embodiment;

FIG. 14A and FIG. 14B are schematic cross-sectional views depicting main processes of a MIS-type AlGaN/GaN-HEMT according to a modified example 3 of the second embodiment;

FIG. 15A and FIG. 15B are schematic cross-sectional views, subsequent to FIG. 14A and FIG. 14B, depicting the main processes of the MIS-type AlGaN/GaN-HEMT according to the modified example 3 of the second embodiment;

FIG. 16 is a connection diagram depicting a schematic structure of a power supply device according to a fourth embodiment; and

FIG. 17 is a connection diagram depicting a schematic structure of a high-frequency amplifier according to a fifth embodiment.

### DESCRIPTION OF EMBODIMENTS

Hereinafter, various embodiments are explained in detail with reference to the drawings. In the various embodiments below, a structure of a compound semiconductor device is explained together with a method of manufacturing the same.

Incidentally, in the drawings below, there are some component members whose size and thickness are not depicted relatively correctly, as a matter of convenience of illustration.

### First Embodiment

In this embodiment, a MIS-type AlGaN/GaN-HEMT is disclosed as a compound semiconductor device.

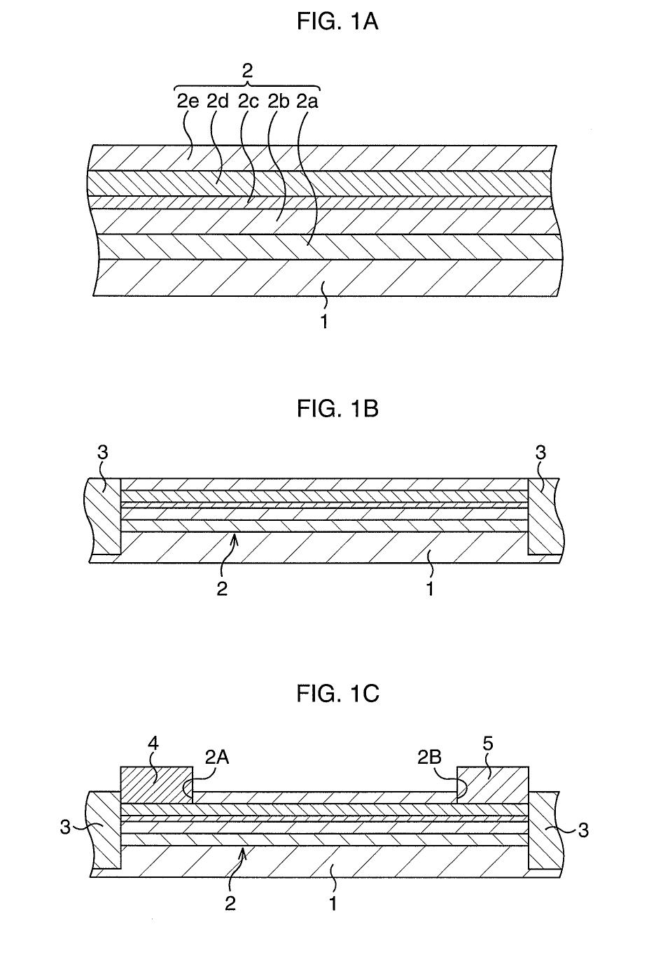

FIG. 1A to FIG. 1C to FIG. 3A and FIG. 3B are schematic cross-sectional views depicting a method of manufacturing a MIS-type AlGaN/GaN-HEMT according to a first embodiment in order of processes.

First, as depicted in FIG. 1A, a compound semiconductor layer 2 is formed on, for example, a semi-insulating SiC substrate 1 as a substrate for growth. The compound semiconductor layer 2 is structured to include: a buffer layer 2a; an electron transit layer 2b; an intermediate layer 2c; an electron supply layer 2d; and a cap layer 2e. In the AlGaN/GaN-HEMT, a two-dimensional electron gas (2DEG) is produced in the vicinity of an interface of the electron transit layer 2b with the electron supply layer 2d (intermediate layer 2c, correctly).

More specifically, compound semiconductors below are each grown on the SiC substrate 1 by the metal organic vapor phase epitaxy (MOVPE: Metal Organic Vapor Phase Epitaxy) method, for example. In place of the MOVPE method, the molecular beam epitaxy (MBE: Molecular Beam Epitaxy) method or the like may also be used.

On the SiC substrate 1, AlN, n-(intentionally-undoped)-GaN, i-AlGaN, n-AlGaN, and n-GaN are sequentially deposited, and the buffer layer 2a, the electron transit layer 2b, the intermediate layer 2c, the electron supply layer 2d, and the cap layer 2e are layered and formed. As for growth conditions of AlN, GaN, AlGaN, and GaN, a mixed gas of a trimethylaluminium gas, a trimethylgallium gas, and an ammonia gas is used as a source gas. According to the growing compound semiconductor layer, whether or not the trimethylaluminium gas being an Al source and the trimethylgallium gas being a Ga source are supplied and flow rates of them are appropriately set. A flow rate of the ammonia gas being a common raw material is set to 100 ccm to 10 LM or so. Further, a growth pressure is set to 50 Torr to 300 Torr or so, and a growth temperature is set to 1000° C. to 1200° C. or so.

When GaN and AlGaN are grown as an n type, as an n-type impurity, for example, a SiH₄ gas containing Si, for example, is added to the source gas at a predetermined flow rate, and Si is doped in GaN and AlGaN. A doping concentration of Si is set to 1×10¹⁸/cm³ or so to 1×10²⁰/cm³ or so, and is set to, for example, 5×10¹⁸/cm³ or so.

Here, the buffer layer 2a is formed to have a film thickness of 0.1 μm or so, the electron transit layer 2b is formed to have a film thickness of 3 μm or so, the intermediate layer 2c is formed to have a film thickness of 5 nm or so, the electron supply layer 2d is formed to have a film thickness of 20 nm or so and to have an Al ratio of 0.2 to 0.3 or so, for example, and the cap layer 2e is formed to have a film thickness of 10 nm or so.

Subsequently, as depicted in FIG. 1B, element isolation structures 3 are formed.

More specifically, for example, argon (Ar) is injected into element isolation regions of the compound semiconductor layer 2. Thereby, the element isolation structures 3 are formed in the compound semiconductor layer 2 and portions of a surface layer of the SiC substrate 1. By the element isolation structures 3, active regions are demarcated on the compound semiconductor layer 2.

Incidentally, the element isolation may also be performed with the use of the STI (Shallow Trench Isolation) method, for example, in place of the above-described injection method.

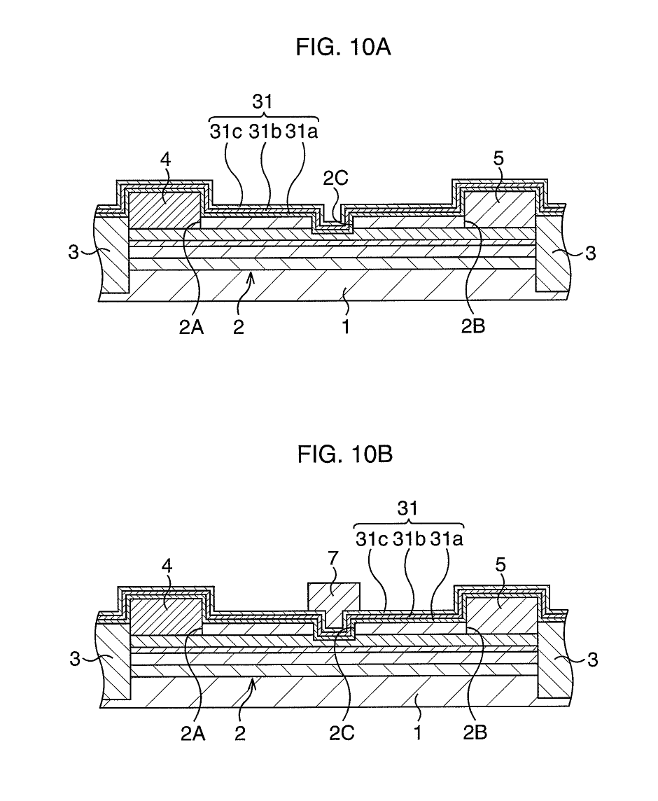

Subsequently, as depicted in FIG. 10, a source electrode 4 and a drain electrode 5 are formed.

More specifically, first, electrode trenches 2A, 2B are formed in the cap layer 2e being formation planned positions for forming the source electrode and the drain electrode on the front surface of the compound semiconductor layer 2.

A resist mask opening at the formation planned positions for forming the source electrode and the drain electrode on the front surface of the compound semiconductor layer 2 is formed. With the use of the above resist mask, the cap layer 2e is dry-etched and is removed. Thereby, the electrode trenches 2A, 2B are formed. In the dry etching, an inert gas such as Ar and a chlorine-based gas such as Cl₂ are used as an etching gas. Here, the electrode trenches may also be formed in a manner that the dry etching is performed to a surface layer portion of the electron supply layer 2d through the cap layer 2e.

As an electrode material, Ta/Al is used, for example. In the electrode formation, for example, a two-layer resist in an eaves structure suitable for the vapor deposition method and the lift-off method is used. The above resist is applied on the compound semiconductor layer 2 and the resist mask opening at the electrode trenches 2A, 2B is formed. With the use of the above resist mask, Ta/Al is deposited. The thickness of Ta is set to 20 nm or so, and the thickness of Al is set to 200 nm or so. By the lift-off method, the resist mask in an eaves structure and Ta/Al deposited thereon are removed. Thereafter, the SiC substrate 1 is subjected to a heat treatment at 550° C. or so in a nitrogen atmosphere, for example, and remaining Ta/Al is made to come into ohmic contact with the electron supply layer 2d. Thus, the source electrode 4 and the drain electrode 5 in which the electrode trenches 2A, 2B are filled with a lower portion of Ta/Al are formed.

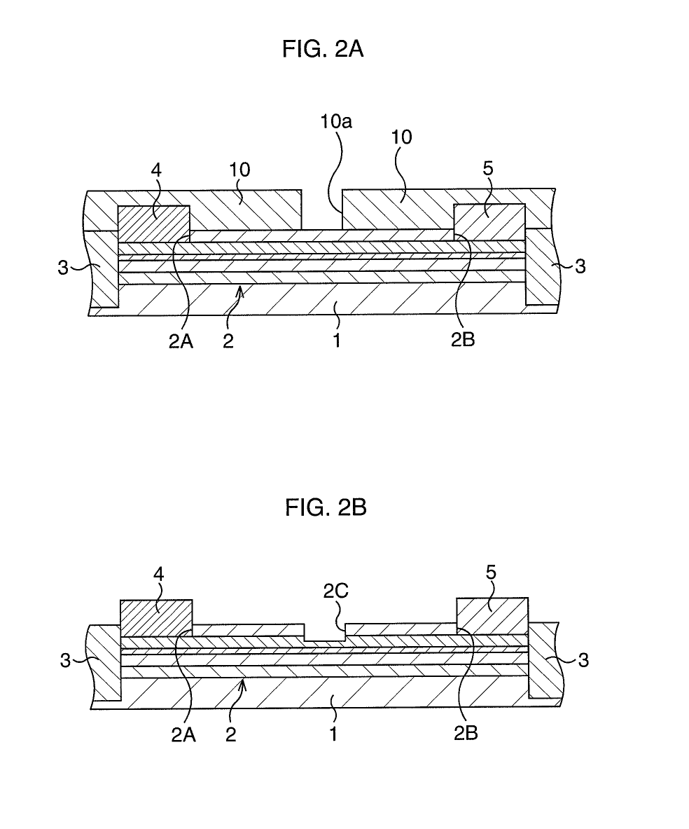

Subsequently, as depicted in FIG. 2A, a resist mask 10 for forming an electrode trench for a gate electrode is formed.

More specifically, a resist is applied on the compound semiconductor layer 2. The resist is processed by the lithography, and an opening 10a is formed at a formation planned position for forming the gate electrode. Thus, the resist mask 10 in which the front surface of the cap layer 2e to be the formation planned position for forming the gate electrode is exposed from the opening 10a is formed.

Subsequently, as depicted in FIG. 2B, an electrode trench 2C is formed at the formation planned position for forming the gate electrode.

With the use of the resist mask 10, dry etching is performed so as to pass through the cap layer 2e and leave one portion of the electron supply layer 2d, and the cap layer 2e is removed. In the dry etching, an inert gas such as Ar and a chlorine-based gas such as Cl₂ are used as an etching gas. At this time, the thickness of the remaining portion of the electron supply layer 2d is set to 0 nm to 20 nm or so, and is set to 1 nm or so, for example. Thereby, the electrode trench 2C is formed. Incidentally, in the formation of the electrode trench for the gate electrode, methods of, for example, wet etching, ion milling, and so on can also be used in place of the above-described dry etching.

The resist mask 10 is removed by an ashing treatment.

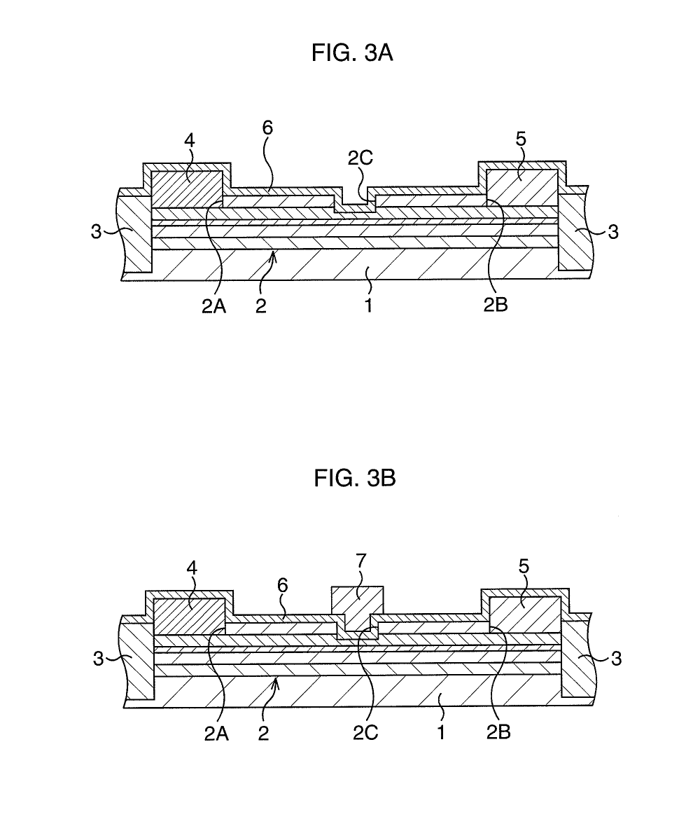

Subsequently, as depicted in FIG. 3A, a gate insulating film 6 is formed.

More specifically, by the plasma CVD method (Plasma-Enhanced Chemical Vapor Deposition: PECVD method), for example, a silicon nitride film (SiN film) is deposited to have a film thickness in a range of 2 nm to 200 nm, which is 20 nm or so, for example, so as to cover the entire surface on the compound semiconductor layer 2 including the top of the source electrode 4 and the top of the drain electrode 5. Thereby, the gate insulating film 6 is formed.

Concrete film forming conditions of the PECVD include source gas species, flow rates of the source gas species, pressure, RF power, and frequency of PF power.

As the source gas, a mixed gas of SiH₄, NH₃, N₂, and He is used, and the flow rate of SiH₄ is set to 3 sccm, the flow rate of NH₃ is set to 1 sccm, the flow rate of N₂ is set to 150 sccm, and the flow rate of He is set to 1000 sccm.

In this embodiment, in order to secure a sufficient hydrogen-terminated group concentration by supplying a great deal of hydrogen to SiN, the RF power in the PECVD is set relatively low within the limit of allowing plasma to be generated. In a state of an excess amount of source gas (reaction rate determining state), a substantially proportional relationship is exhibited between the pressure and the RF power in the PECVD. It is conceivable that if the above-described respective flow rates of gas are applied, SiN is in the reaction rate determining state.

When the foregoing is considered, pressure P and RF power P_{RF} are set as follows.

20 W≦P_{RF}≦200 W, and P_{RF}/P=α (α:constant)

Accordingly, when the RF power P_{RF} is determined to a predetermined value within the above-described range, the pressure is determined uniquely with the use of the constant α. Here, the pressure is set to, for example, 1500 mTorr or so, the RF power is set to, for example, 80 W or so, and the frequency of RF power is set to 13.56 MHz.

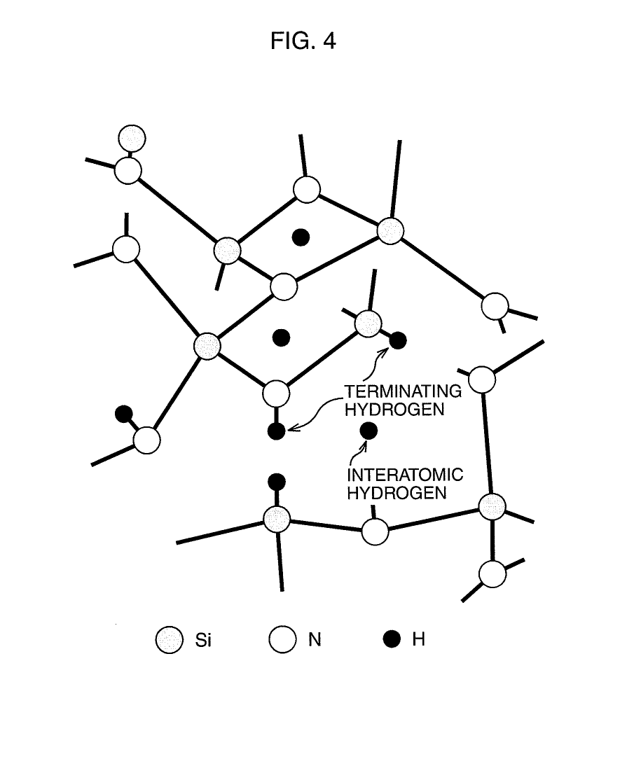

A bonding state of SiN of the gate insulating film 6 formed according to this embodiment is depicted in FIG. 4.

In SiN of the gate insulating film 6, unbonded bonds caused by bonding defects of Si and N that are inevitably included in SiN are sufficiently terminated by hydrogen (H) (hereinafter, the bonding defects of Si and N are simply described as dangling bonds). In other words, the ratio of the unbonded bonds terminated by hydrogen to all the dangling bonds can be evaluated to be sufficient for reducing charge traps in the gate insulating film 6. Further, collapse of terminated hydrogen bonding groups due to thermal change is expected to occur, so that excess interatomic hydrogen having a concentration sufficient to compensate the collapse is contained in SiN. The disposition of high-concentration interatomic hydrogen makes it possible to cause the hydrogen termination again even in the case when a dehydrogenation reaction progresses by heating and then hydrogen is released to the outside from SiN.

As for the SiN film formed under the above-described forming conditions, in the case when SiN of the SiN film is represented as SiₓN_{y}, a composition ratio x/y of Si/N is set to

(3/4)−15%≦x/y≦(3/4)+15%,

namely to a value within a range of

0.638≦x/y≦0.863. Further, a hydrogen-terminated group concentration C_{H1} is set to a value within a range of

2×10²²/cm³≦C_{H1}≦5×10²²/cm³.

Further an interatomic hydrogen concentration C_{H2} is set to a value within a range of

2×10²¹/cm³≦C_{H2}≦6×10²¹/cm³.

Making the composition ratio x/y of Si/N fall within the range of (3/4)±15% means that SiN is allowed to slightly deviate from the composition of Si₃N₄ and it is directed that the dangling bonds of SiN are compensated by hydrogen.

When the hydrogen-terminated group concentration C_{H1} is smaller than 2×10²²/cm³, it becomes difficult to sufficiently terminate the above-described dangling bonds by hydrogen. When the hydrogen-terminated group concentration C_{H1} is larger than 5×10²²/cm³, the hydrogen-terminated group concentration C_{H1} is not actual as SiN, and it becomes impossible to secure sufficient insulation performance as the gate insulating film. Thus, setting the hydrogen-terminated group concentration C_{H1} to a value within the above-described range makes it possible to sufficiently terminate the dangling bonds by hydrogen while maintaining the excellent property as the gate insulating film.

In order to confirm a good application range of the hydrogen-terminated group concentration C_{H1} in SiN in this embodiment, various experiments were conducted.

In an experiment 1, a relationship between the hydrogen-terminated group concentration C_{H1} and a leak current was examined. In the experiment 1, a capacitor in which SiN different in the hydrogen-terminated group concentration C_{H1} is formed to have a film thickness of 50 nm and is structured as a capacitor film was used.

In an experiment 2, a relationship between the hydrogen-terminated group concentration C_{H1} and a concentration corresponding to unpaired electrons, namely an amount of dangling bonds in SiN was examined.

In an experiment 3, a relationship between the hydrogen-terminated group concentration C_{H1} and a current collapse ratio was examined. In the case when with a gate voltage Vg within a predetermined range, a drain voltage Vd is applied to SiN to be the maximum value, a drain voltage Id in the predetermined drain voltage Vd (for example, 5 V) is set to Id₁. In the case when with the gate voltage Vg within a predetermined range, the drain voltage Vd is applied to SiN to be a value smaller than that in the above-described case, the drain voltage Id in the predetermined drain voltage Vd (for example, 5 V) is set to Id₂. The current collapse ratio is defined as (Id₁/Id₂)×100(%).

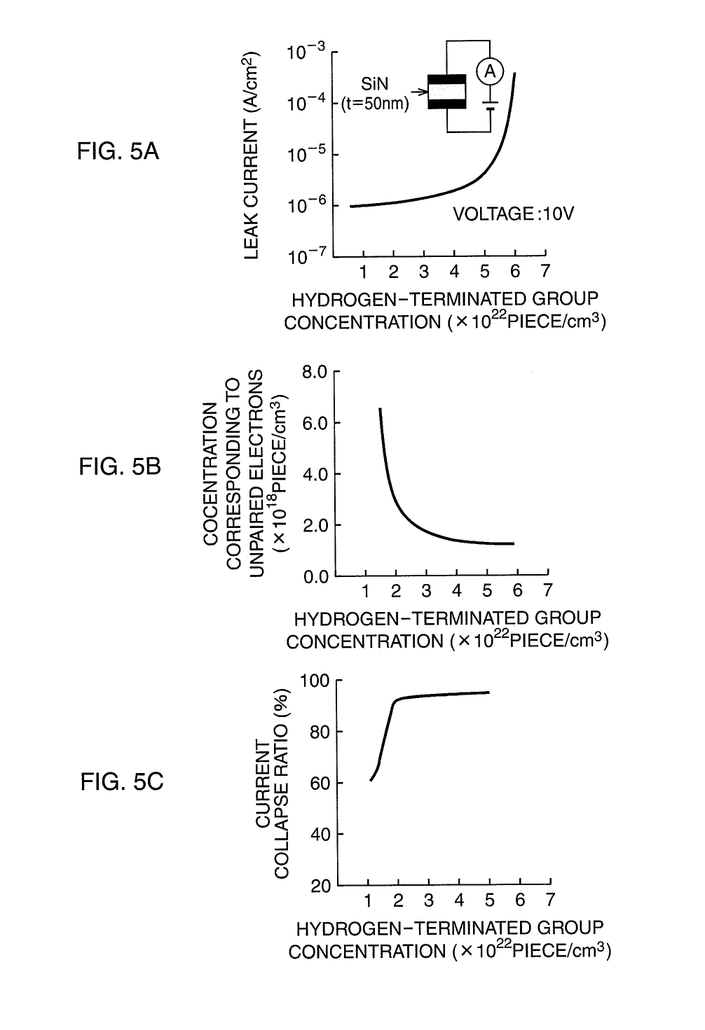

A result of the experiment 1 is depicted in FIG. 5A, a result of the experiment 2 is depicted in FIG. 5B, and a result of the experiment 3 is depicted in FIG. 5C respectively.

As depicted in FIG. 5A, when the value of the hydrogen-terminated group concentration C_{H1} is 5×10²²/cm³ or less, the leak current becomes a substantially constant low value. When the value of the hydrogen-terminated group concentration C_{H1} exceeds 5×10²²/cm³, the value of the leak current steeply increases. From the above result, the upper limit value of the hydrogen-terminated group concentration C_{H1} of SiN according to this embodiment can be evaluated to be 5×10²²/cm³ or so in order to suppress the leak current to a low value.

As depicted in FIG. 5B, when the value of the hydrogen-terminated group concentration C_{H1} is 2×10²²/cm³ or more, the concentration corresponding to unpaired electrons becomes a substantially constant low value. When the value of the hydrogen-terminated group concentration C_{H1} falls short of 2×10²²/cm³, the value of the concentration corresponding to unpaired electrons steeply increases. From the above result, the lower limit value of the hydrogen-terminated group concentration C_{H1} of SiN according to this embodiment can be evaluated to be 2×10²²/cm³ or so in order to sufficiently terminate the dangling bonds of SiN by hydrogen.

As depicted in FIG. 5C, when the value of the hydrogen-terminated group concentration C_{H1} is 2×10²²/cm³ or more, the high current collapse ratio of 95% or so or more is maintained. When the value of the hydrogen-terminated group concentration C_{H1} falls short of 2×10²²/cm³, the current collapse ratio steeply reduces. From the above result, the lower limit value of the hydrogen-terminated group concentration C_{H1} of SiN according to this embodiment can be evaluated to be 2×10²²/cm³ or so in order to maintain the high current collapse ratio.

From the results of the experiments 1 to 3, the hydrogen-terminated group concentration C_{H1} in SiN in this embodiment is prescribed to be not less than 2×10²²/cm³ nor more than 5×10²²/cm³, and thereby it is confirmed that the excellent gate insulating film in which an amount of the leak current is reduced and the dangling bonds are reduced is obtained.

When the interatomic hydrogen concentration C_{H2} is smaller than 2×10²¹/cm³, it becomes difficult to sufficiently compensate the collapse of terminated hydrogen bonding groups. When the interatomic hydrogen concentration C_{H2} is larger than 6×10²¹/cm³, it becomes impossible to secure sufficient insulation performance as the gate insulating film. Thus, setting the interatomic hydrogen concentration C_{H2} to a value within the above-described range makes it possible to sufficiently compensate the collapse of terminated hydrogen bonding groups without causing a problem when the gate insulating film is used.

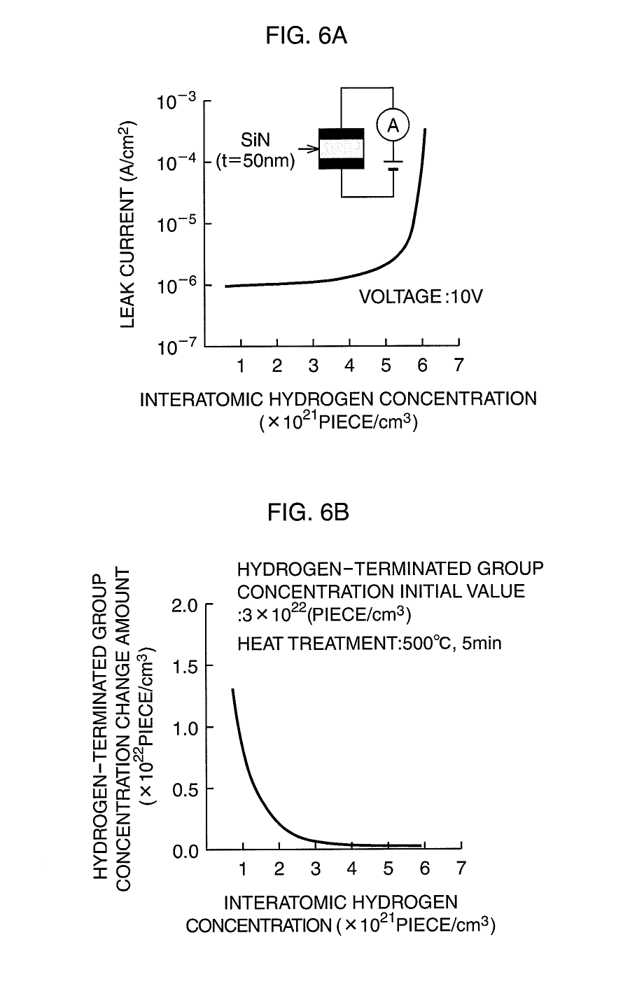

In order to confirm a good application range of the interatomic hydrogen concentration C_{H2} in SiN in this embodiment, various experiments were conducted. In an experiment 4, a relationship between the interatomic hydrogen concentration C_{H2} and a leak current was examined. In the experiment 4, a capacitor in which SiN different in the interatomic hydrogen concentration C_{H2} is formed to have a film thickness of 50 nm and is structured as a capacitor film was used. In an experiment 5, a relationship between the interatomic hydrogen concentration C_{H2} and a change amount of the hydrogen-terminated group concentration C_{H1} was examined. In the experiment 5, an initial value of the hydrogen-terminated group concentration C_{H1} of SiN was set to 3×10²²/cm³. SiN was subjected to a heat treatment under conditions that the temperature is at 500° C. and the time is for 5 minutes. A result of the experiment 4 is depicted in FIG. 6A and a result of the experiment 5 is depicted in FIG. 6B respectively.

As depicted in FIG. 6A, when the value of the interatomic hydrogen concentration C_{H2} is 6×10²¹/cm³ or less, the leak current becomes a substantially constant low value. When the value of the interatomic hydrogen concentration C_{H2} exceeds 6×10²¹/cm³, the value of the leak current steeply increases. From the above result, the upper limit value of the interatomic hydrogen concentration C_{H2} of SiN according to this embodiment can be evaluated to be 6×10²¹/cm³ or so in order to suppress the leak current to a low value.

As depicted in FIG. 6B, when the value of the interatomic hydrogen concentration C_{H2} is 2×10²¹/cm³ or more, the change amount of the hydrogen-terminated group concentration C_{H1} becomes a quite low value. When the value of the interatomic hydrogen concentration C_{H2} falls short of 2×10²¹/cm³, the change amount of the hydrogen-terminated group concentration C_{H1} steeply increases. This is conceivably because of a mechanism below. When SiN terminated by hydrogen is subjected to the heat treatment, hydrogen is released from SiN by the dehydrogenation reaction. In SiN in which the value of the interatomic hydrogen concentration C_{H2} falls short of 2×10²¹/cm³, it is not possible to sufficiently compensate hydrogen released to the outside by interatomic hydrogen, and thus the change amount of the hydrogen-terminated group concentration C_{H1} is very large. In contrast with the above, when the value of the interatomic hydrogen concentration C_{H2} is 2×10²¹/cm³ or more, it is possible to sufficiently compensate hydrogen released to the outside by interatomic hydrogen, and thus the change amount of the hydrogen-terminated group concentration C_{H1} is small. From the above result, the lower limit value of the interatomic hydrogen concentration C_{H2} of SiN according to this embodiment can be evaluated to be 2×10²¹/cm³ or so.

From the results in the experiments 4 and 5, the interatomic hydrogen concentration C_{H2} in SiN in this embodiment is prescribed to be not less than 2×10²¹/cm³ nor more than 6×10²¹/cm³, and thereby it is confirmed that the excellent gate insulating film in which the reduced dangling bonds are maintained even if the collapse of hydrogen bonding groups due to thermal change occurs is obtained.

The composition ratio x/y of Si/N is measured by the X-ray photoelectron spectroscopy method (X-ray Photoelectron Spectroscopy: XPS). The hydrogen-terminated group concentration C_{H1} is measured by the infrared absorption method. The interatomic hydrogen concentration C_{H2} is measured by the hydrogen forward scattering method (Hydrogen Forward Scattering: HFS) and the Rutherford backscattering spectrometry method (Rutherford Backscattering Spectrometry: RBS).

In the SiN film in this embodiment, the composition ratio x/y of Si/N is set to, for example, (0.84) or so, the hydrogen-terminated group concentration C_{H1} is set to, for example, 2.1×10²²/cm³ or so, and the interatomic hydrogen concentration C_{H2} is set to, for example, 3×10²¹/cm³ or so. At this time, a concentration corresponding to remaining unpaired electrons (concentration of the remaining dangling bonds) is measured by the electron spin resonance method (Electron Spin Resonance: ESR) and 2.6×10¹⁸/cm³ or so is obtained.

The gate insulating film 6 formed of the above SiN film is a film in which its composition is close to Si₃N₄, the dangling bonds are sufficiently terminated by hydrogen (H), and interatomic hydrogen having a concentration sufficient to compensate the collapse of hydrogen bonding groups is contained. The above gate insulating film 6 is formed in a state where the dangling bonds are quite reduced and charge traps are significantly reduced.

Subsequently, as depicted in FIG. 3B, a gate electrode 7 is formed.

More specifically, first, a lower-layer resist (for example, brand name PMGI: made by MicroChem Corp, U.S.) and an upper-layer resist (for example, brand name PF132-A8: made by Sumitomo Chemical Company, Limited) are applied and formed on the gate insulating film 6 respectively by the spin coat method, for example. An opening of, for example, 1.5 μm or so in diameter is formed in the upper-layer resist by ultraviolet exposure. Next, the upper-layer resist is used as a mask, and the lower-layer resist is wet etched with an alkaline developing solution. Next, the upper-layer resist and the lower-layer resist are used as a mask, and a gate metal (Ni: 10 nm or so in film thickness/Au: 300 nm or so in film thickness) is vapor deposited on the entire surface including the inside of the opening. Thereafter, the SiC substrate 1 is soaked in N-methyl-pyrrolidinone heated to 80° C., and the lower-layer resist and the upper-layer resist and the unnecessary gate metal are removed by the lift-off method. Thus, the gate electrode 7 in which the electrode trench 2C is filled with part of the gate metal via the gate insulating film 6 is formed.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this embodiment, there is fabricated the highly-reliable AlGaN/GaN-HEMT in which charge traps in the gate insulating film 6 (particularly, charge traps on an interface of the gate insulating film 6 with the gate electrode 7 and in a vicinity region of the interface, or on an interface of the gate insulating film 6 with the compound semiconductor layer 2 and in a vicinity region of the interface) are significantly reduced and a change in electric properties is suppressed.

### Modified Examples

Hereinafter, various modified examples in the first embodiment are explained.

In the following various modified examples, similarly to the first embodiment, a MIS-type AlGaN/GaN-HEMT is disclosed as a compound semiconductor device, but differs from that in the first embodiment in that the structure of the gate insulating film is slightly different.

### Modified Example 1

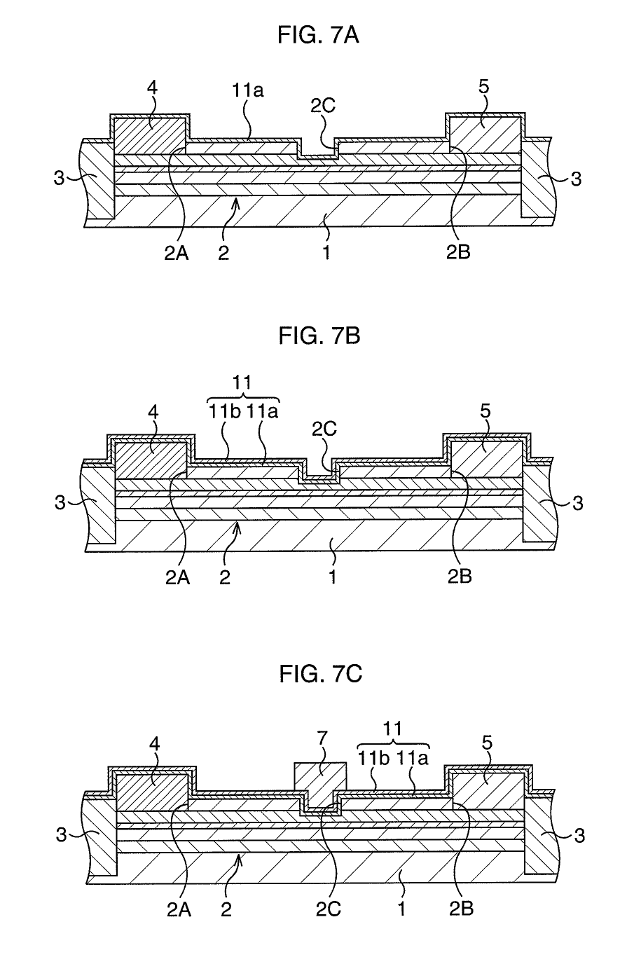

FIG. 7A to FIG. 7C are schematic cross-sectional views depicting main processes of a MIS-type AlGaN/GaN-HEMT according to a modified example 1 in the first embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 7A and FIG. 7B, a gate insulating film 11 is formed.

First, as depicted in FIG. 7A, a first insulating film 11a is formed.

More specifically, under the same forming conditions as those of the SiN film of the gate insulating film 6 depicted in FIG. 3A in the first embodiment, a SiN film is deposited to have a film thickness of 5 nm or so by the PECVD method so as to cover the entire surface on the compound semiconductor layer 2 including the top of a source electrode 4 and the top of a drain electrode 5. Thereby, the first insulating film 11a is formed. The first insulating film 11a is formed to have the same composition and property as those of the gate insulating film 6 in the first embodiment except that the film thickness is different.

Next, as depicted in FIG. 7B, a second insulating film 11b is formed.

As an insulating material of the second insulating film 11b, a material having a band gap higher than that of SiN of the first insulating film 11a is used. As the insulating material of the second insulating film 11b, alumina (Al₂O₃), aluminum nitride (AlN), tantalum oxide (TaO), and so on are cited. Here, the case of using Al₂O₃ is described as an example.

On the first insulating film 11a, Al₂O₃ is deposited to have a film thickness of 15 nm or so by the atomic layer deposition method (Atomic Layer Deposition: ALD method), for example. Thereby, the second insulating film 11b is formed. Incidentally, the deposition of Al₂O₃ may also be performed by, for example, the CVD method or the like in place of the ALD method. Thus, the gate insulating film 11 in which the first insulating film 11a and the second insulating film 11b are sequentially layered is formed so as to cover the top of the compound semiconductor layer 2 including an internal surface of the electrode trench 2C.

The gate insulating film 11 includes the first insulating film 11a, so that dangling bonds are quite reduced and charge traps are significantly reduced. Further, the gate insulating film 11 includes the second insulating film 11b, so that a gate withstand voltage of the gate electrode is improved. That is, the application of the gate insulating film 11 makes it possible to achieve a significant reduction in charge trap density while achieving the high gate withstand voltage of the gate electrode.

Subsequently, as depicted in FIG. 7C, similarly to the first embodiment, a gate electrode 7 is formed through the process in FIG. 3B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 11 (particularly, charge traps on an interface of the gate insulating film 11 with the compound semiconductor layer 2 and in a vicinity region of the interface) are significantly reduced and a change in electric properties is suppressed while achieving the high gate withstand voltage of the gate electrode 7.

### Modified Example 2

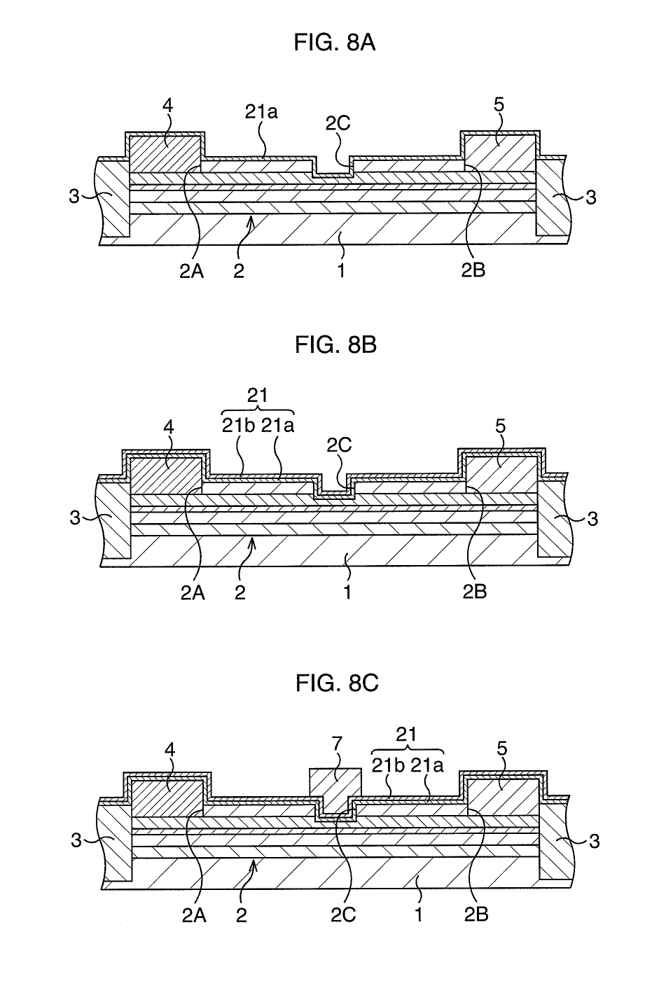

FIG. 8A to FIG. 8C are schematic cross-sectional views depicting main processes of a MIS-type AlGaN/GaN-HEMT according to a modified example 2 in the first embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 8A and FIG. 8B, a gate insulating film 21 is formed.

More specifically, first, as depicted in FIG. 8A, similarly to the formation of the second insulating film 11b in FIG. 7B explained in the modified example 1, Al₂O₃ is deposited to have a film thickness of 45 nm or so by the ALD method so as to cover the entire surface on the compound semiconductor layer 2 including the top of a source electrode 4 and the top of a drain electrode 5. Thereby, a first insulating film 21a is formed.

Here, a SiC substrate 1 may also be subjected to a heat treatment.

Concretely, the SiC substrate 1 is heated for 5 minutes or so in a range of 400° C. to 1200° C., for example. Thereby, a bonding state of the first insulating film 21a is improved. By the introduction of the above heat treatment, hydrogen termination collapse of the gate insulating film 21 is suppressed, and a state of a stable and low concentration corresponding to unpaired electrons is maintained. Further, Al₂O₃ in which the bonding state is improved by the heat treatment is employed, and thereby a gate withstand voltage is further stabilized.

Next, as depicted in FIG. 8B, similarly to the formation of the first insulating film 11a in FIG. 7A explained in the modified example 1, SiN is deposited on the first insulating film 21a to have a film thickness of 5 nm or so by the PECVD method. Thereby, a second insulating film 21b is formed. The second insulating film 21b is formed to have the same composition and property as those of the gate insulating film 6 in the first embodiment except that the film thickness is different.

Thus, the gate insulating film 21 in which the first insulating film 21a and the second insulating film 21b are sequentially layered is formed so as to cover the top of the compound semiconductor layer 2 including an internal surface of the electrode trench 2C.

The gate insulating film 21 includes the second insulating film 21b, so that dangling bonds are quite reduced and charge traps are significantly reduced. Further, the gate insulating film 21 includes the first insulating film 21a, so that the gate withstand voltage of the gate electrode is improved. That is, the application of the gate insulating film 21 makes it possible to achieve a significant reduction in charge trap density while achieving the high gate withstand voltage of the gate electrode.

Subsequently, as depicted in FIG. 8C, similarly to the first embodiment, a gate electrode 7 is formed through the process in FIG. 3B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 21 (particularly, charge traps on an interface of the gate insulating film 21 with the gate electrode 7 and in a vicinity region of the interface) are significantly reduced and a change in electric properties is suppressed while achieving the high gate withstand voltage of the gate electrode 7.

### Modified Example 3

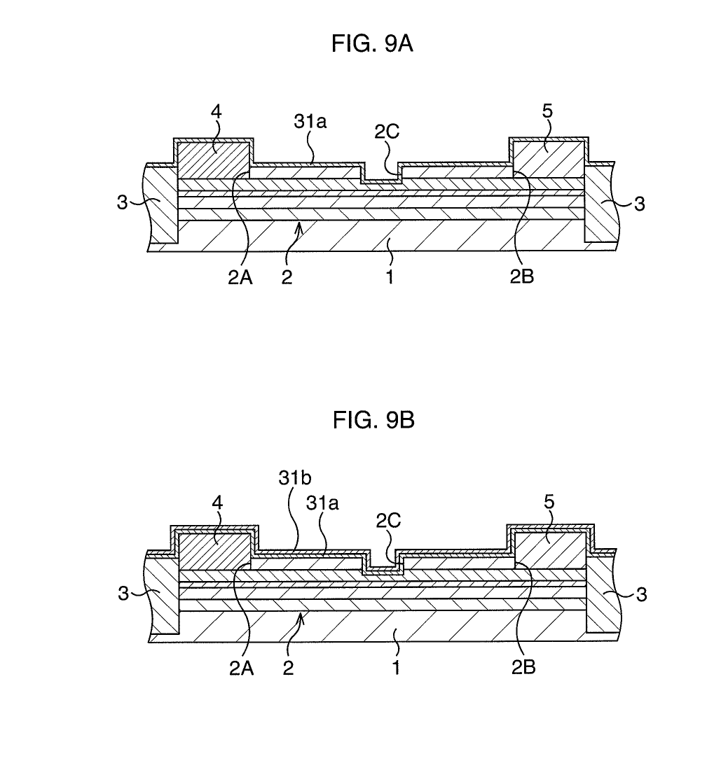

FIG. 9A and FIG. 9B and FIG. 10A and FIG. 10B are schematic cross-sectional views depicting main processes of a MIS-type AlGaN/GaN-HEMT according to a modified example 3 in the first embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 9A, FIG. 9B, and FIG. 10A, a gate insulating film 31 is formed.

More specifically, first, as depicted in FIG. 9A, similarly to the formation of the first insulating film 11a in FIG. 7A explained in the modified example 1, SiN is deposited to have a film thickness of 5 nm or so by the PECVD method so as to cover the entire surface on a SiC substrate 1 including the top of a source electrode 4 and the top of a drain electrode 5. Thereby, a first insulating film 31a is formed. The first insulating film 31a is formed to have the same composition and property as those of the gate insulating film 6 in the first embodiment except that the film thickness is different.

Next, as depicted in FIG. 9B, similarly to the formation of the second insulating film 11b in FIG. 7B explained in the modified example 1, Al₂O₃ is deposited on the first insulating film 31a to have a film thickness of 10 nm or so by the ALD method. Thereby, a second insulating film 31b is formed.

Next, as depicted in FIG. 10A, similarly to the formation of the first insulating film 31a, SiN is deposited on the second insulating film 31b to have a film thickness of 5 nm or so by the PECVD method. Thereby, a third insulating film 31c is formed. The third insulating film 31c is formed to have the same composition and property as those of the gate insulating film 6 in the first embodiment except that the film thickness is different.

Thus, the gate insulating film 31 in which the first insulating film 31a, the second insulating film 31b, and the third insulating film 31c are sequentially layered is formed so as to cover the top of the compound semiconductor layer 2 including an internal surface of the electrode trench 2C.

The gate insulating film 31 includes the first and third insulating films 31a, 31c, so that dangling bonds are quite reduced and charge traps are significantly reduced. Further, in the above case, the structure in which the second insulating film 31b is sandwiched between the first insulating film 31a and the third insulating film 31c is made, so that a state where dangling bonds on the front surface and rear surface of the gate insulating film 31 are quite reduced and charge traps are significantly reduced is made. Further, the gate insulating film 31 includes the second insulating film 31b, so that a gate withstand voltage of the gate electrode is improved. That is, the application of the gate insulating film 31 makes it possible to achieve a further significant reduction in charge trap density while achieving the high gate withstand voltage of the gate electrode.

Subsequently, as depicted in FIG. 10B, similarly to the first embodiment, a gate electrode 7 is formed through the process in FIG. 3B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 31 (particularly, charge traps on an interface of the gate insulating film 31 with the gate electrode 7 and in a vicinity region of the interface, or on an interface of the gate insulating film 31 with the compound semiconductor layer 2 and in a vicinity region of the interface) are significantly reduced and a change in electric properties is suppressed while achieving the high gate withstand voltage of the gate electrode 7.

### Second Embodiment

In this embodiment, similarly to the first embodiment, a MIS-type AlGaN/GaN-HEMT is disclosed as a compound semiconductor device, but differs from that of the first embodiment in that the structure of the gate insulating film is different.

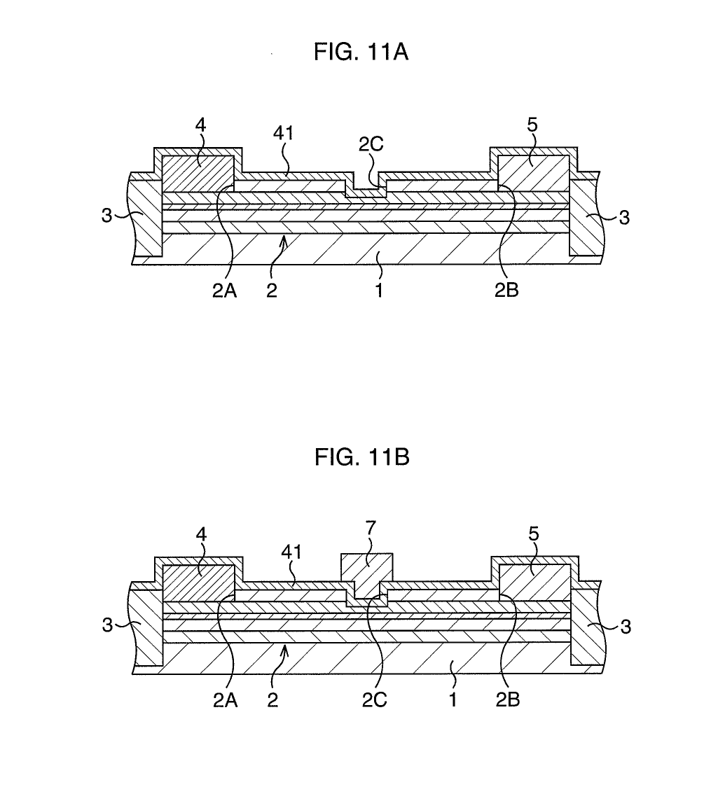

FIG. 11A and FIG. 11B are schematic cross-sectional views depicting main processes of a MIS-type AlGaN/GaN-HEMT according to a second embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 11A, a gate insulating film 41 is formed.

More specifically, by the PECVD method, for example, a silicon oxynitride film (SiON film) is deposited to have a film thickness in a range of 2 nm to 200 nm, which is for example, 20 nm or so, so as to cover the entire surface on a SiC substrate 1 including the top of a source electrode 4 and the top of a drain electrode 5. Thereby, the gate insulating film 41 is formed.

Concrete film forming conditions of the PECVD include source gas species, flow rates of the source gas species, pressure, RF power, and frequency of PF power.

As the source gas, a mixed gas of SiH₄, NH₃, N₂O, and N₂ is used, and the flow rate of SiH₄ is set to 3 sccm, the flow rate of NH₃ is set to 3 sccm, the flow rate of N₂O is set to 5 sccm, and the flow rate of N₂ is set to 1000 sccm respectively.

In this embodiment, in order to secure a sufficient hydrogen-terminated group concentration by supplying a great deal of hydrogen to SiON, the RF power in the PECVD is set relatively low within the limit of allowing plasma to be generated. In a state of an excess amount of source gas (reaction rate determining state), a substantially proportional relationship is exhibited between the pressure and the RF power in the PECVD. It is conceivable that if the above-described respective flow rates of gas are applied, SiON is in the reaction rate determining state.

When the foregoing is considered, pressure P and RF power P_{RF} are set as follows.

20 W≦P_{RF}≦200 W, and P_{RF}/P=α (α: constant)

Accordingly, when the RF power P_{RF} is determined to a predetermined value within the above-described range, the pressure is determined uniquely with the use of the constant α. Here, the pressure is set to, for example, 1500 mTorr or so, the RF power is set to, for example, 50 W or so, and the frequency of RF power is set to 13.56 MHz.

SiON has a property in which at the time when atomic bonding is produced, an effect of alleviating bond distortion is enhanced and bonding defects do not occur easily. Further, SiON deposited as described above do not have many unbonded bonds caused by bonding defects of Si, O, and N that are inevitably included in SiON (hereinafter, the bonding defects of Si, O, and N are simply described as dangling bonds). Further, remaining unbonded bonds are terminated by hydrogen (H). In other words, the ratio of the unbonded bonds terminated by hydrogen to all the dangling bonds can be evaluated to be sufficient for reducing charge traps in the gate insulating film 41. Further, collapse of terminated hydrogen bonding groups due to thermal change is expected to occur, so that SiON contains excess interatomic hydrogen having a concentration sufficient to compensate the collapse. The disposition of high-concentration interatomic hydrogen makes it possible to cause the hydrogen termination again even in the case when a dehydrogenation reaction progresses by heating and then hydrogen is released to the outside from SiON.

As for the SiON film formed under the above-described forming conditions, in the case when SiON of the SiON film is represented as SiₓO_{y}N_{z}, a composition ratio x:y:z of Si:O:N is set to

x:y:z=0.32±20%:0.30±20%:0.38±20%, namely to a value within a range of

x:y:z=0.256 to 0.384:0.240 to 0.360:0.304 to 0.456 and x+y+z=1. Further, a hydrogen-terminated group concentration C_{H1} is set to a value within a range of

2×10²²/cm³≦C_{H1}≦5×10²²/cm³. Further, an interatomic hydrogen concentration C_{H2} is set to a value within a range of

2×10²¹/cm³≦C_{H2}≦6×10²¹/cm³.

Applying the composition ratio x:y:z of Si:O:N to an application range as described above means that it is directed that the dangling bonds are compensated by hydrogen.

When the hydrogen-terminated group concentration C_{H1} is smaller than 2×10²²/cm³, it becomes difficult to sufficiently terminate the above-described dangling bonds by hydrogen. When the hydrogen-terminated group concentration C_{H1} is larger than 5×10²²/cm³, the hydrogen-terminated group concentration C_{H1} is not actual as a SiON insulating film, and it becomes impossible to secure sufficient insulation performance as the gate insulating film. Thus, setting the hydrogen-terminated group concentration C_{H1} to a value within the above-described range makes it possible to sufficiently terminate the dangling bonds by hydrogen while maintaining the excellent property as the gate insulating film.

When the interatomic hydrogen concentration C_{H2} is smaller than 2×10²¹/cm³, it becomes difficult to sufficiently compensate the collapse of terminated hydrogen bonding groups. When the interatomic hydrogen concentration C_{H2} is larger than 6×10²¹/cm³, it becomes impossible to secure sufficient insulation performance as the gate insulating film. Thus, setting the interatomic hydrogen concentration C_{H2} to a value within the above-described range makes it possible to sufficiently compensate the collapse of terminated hydrogen bonding groups without causing a problem when the gate insulating film is used.

Incidentally, results substantially equal to those in the respective experiments, regarding SiN in the first embodiment, depicted in FIG. 5A to FIG. 5C and FIG. 6A and FIG. 6B are also obtained regarding SiON in this embodiment.

That is, the hydrogen-terminated group concentration C_{H1} in SiON in this embodiment is prescribed to be not less than 2×10²²/cm³ nor more than 5×10²²/cm³, and thereby the excellent gate insulating film in which an amount of leak current is reduced and the dangling bonds are reduced is obtained.

Further, the interatomic hydrogen concentration C_{H2} in SiON in this embodiment is prescribed to be not less than 2×10²¹/cm³ nor more than 6×10²¹/cm³, and thereby the excellent gate insulating film in which the reduced dangling bonds are maintained even if the collapse of hydrogen bonding groups due to thermal change occurs is obtained.

The composition ratio x:y:z of Si:O:N is measured by the XPS. The hydrogen-terminated group concentration C_{H1} is measured by the infrared absorption method. The interatomic hydrogen concentration C_{H2} is measured by the HFS and the RBS.

In the SiON film in this embodiment, the composition ratio x:y:z of Si:O:N is set to, for example, 0.32:0.3:0.38 or so, the hydrogen-terminated group concentration C_{H1} is set to, for example, 3×10²²/cm³ or so, and the interatomic hydrogen concentration C_{H2} is set to, for example, 3×10²¹/cm³ or so. At this time, a concentration corresponding to remaining unpaired electrons is measured by the ESR and 1.8×10¹⁸/cm³ or so is obtained.

The gate insulating film 41 formed of the above SiON film is a film in which the dangling bonds are reduced in substance, the remaining dangling bonds are sufficiently terminated by hydrogen (H), and interatomic hydrogen having a concentration sufficient to compensate the collapse of hydrogen bonding groups is contained. The above gate insulating film 41 is formed in a state where the dangling bonds are quite reduced and charge traps are significantly reduced.

Subsequently, as depicted in FIG. 11B, a gate electrode 7 is formed through the process in FIG. 3B similarly to the first embodiment.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 41 (particularly, charge traps on an interface of the gate insulating film 41 with the gate electrode 7 and in a vicinity region of the interface, or on an interface of the gate insulating film 41 with the compound semiconductor layer 2 and in a vicinity region of the interface) are further significantly reduced and a change in electric properties is suppressed while achieving a high gate withstand voltage of the gate electrode 7.

### Modified Examples

Hereinafter, various modified examples in the second embodiment are explained.

In the following various modified examples, similarly to the second embodiment, a MIS-type AlGaN/GaN-HEMT is disclosed as a compound semiconductor device, but differs from that in the second embodiment in that the structure of the gate insulating film is slightly different.

### Modified Example 1

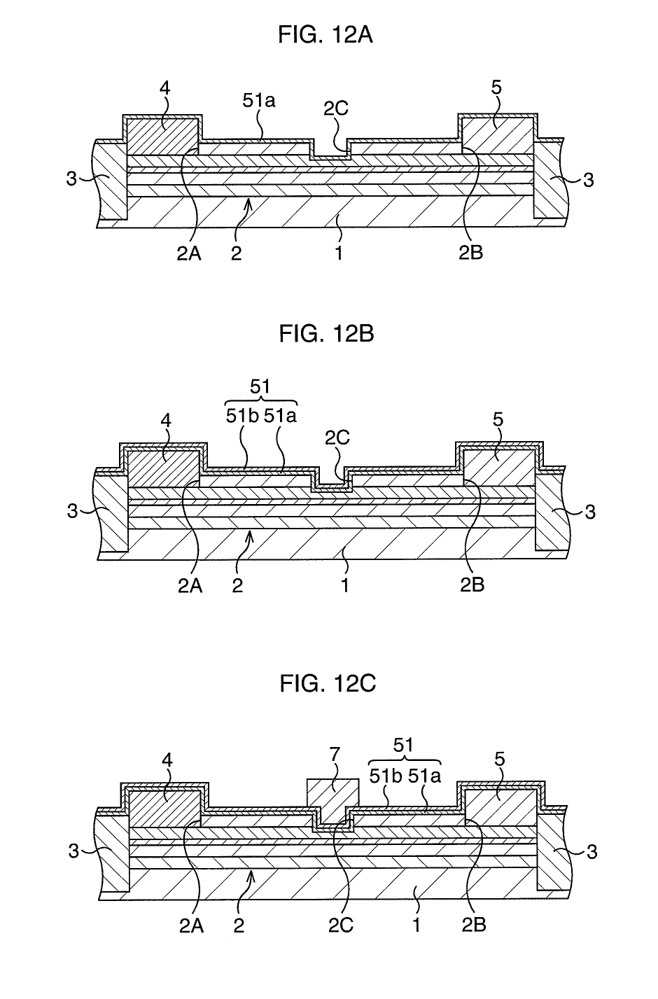

FIG. 12A to FIG. 12C are schematic cross-sectional views depicting main processes of a MIS-type AlGaN/GaN-HEMT according to a modified example 1 in the second embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 12A and FIG. 12B, a gate insulating film 51 is formed.

First, as depicted in FIG. 12A, a first insulating film 51a is formed.

More specifically, under the same forming conditions as those of the SiON film of the gate insulating film 41 depicted in FIG. 11A in the second embodiment, a SiON film is deposited to have a film thickness of 5 nm or so by the PECVD method so as to cover the entire surface on a SiC substrate 1 including the top of a source electrode 4 and the top of a drain electrode 5. Thereby, the first insulating film 51a is formed. The first insulating film 51a is formed to have the same composition and property as those of the gate insulating film 41 in the second embodiment except that the film thickness is different.

Next, as depicted in FIG. 12B, a second insulating film 51b is formed.

As an insulating material of the second insulating film 51b, a material having a band gap higher than that of SiON of the first insulating film 51a is used. As the insulating material of the second insulating film 51b, Al₂O₃, AlN, TaO, and so on are cited. Here, the case of using Al₂O₃ is described as an example.

On the first insulating film 51a, Al₂O₃ is deposited to have a film thickness of 15 nm or so by the atomic layer deposition method (Atomic Layer Deposition: ALD method), for example. Thereby, the second insulating film 51b is formed. Incidentally, the deposition of Al₂O₃ may also be performed by, for example, the CVD method or the like in place of the ALD method. Thus, the gate insulating film 51 in which the first insulating film 51a and the second insulating film 51b are sequentially layered is formed so as to cover the top of the compound semiconductor layer 2 including an internal surface of the electrode trench 2C.

The gate insulating film 51 includes the first insulating film 51a, so that dangling bonds are quite reduced and charge traps are significantly reduced. Further, the gate insulating film 51 includes the second insulating film 51b, so that a gate withstand voltage of the gate electrode is improved. That is, the application of the gate insulating film 51 makes it possible to achieve a significant reduction in charge trap density while achieving the high gate withstand voltage of the gate electrode.

Subsequently, as depicted in FIG. 12C, similarly to the second embodiment, a gate electrode 7 is formed through the process in FIG. 11B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 51 (particularly, charge traps on an interface of the gate insulating film 51 with the compound semiconductor layer 2 and in a vicinity region of the interface) are further significantly reduced and a change in electric properties is suppressed while achieving the high gate withstand voltage of the gate electrode 7.

### Modified Example 2

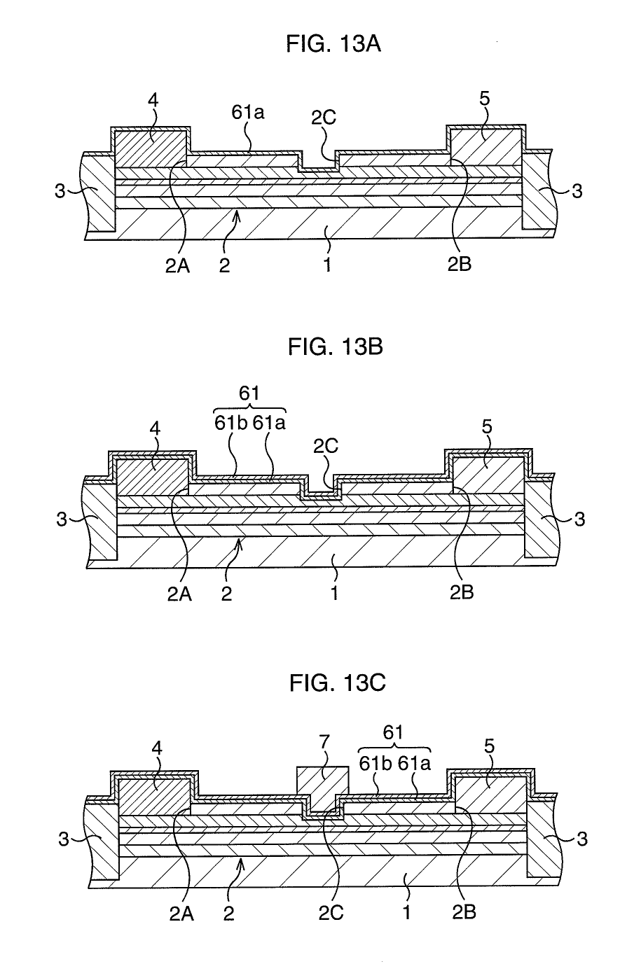

FIG. 13A to FIG. 13C are schematic cross-sectional views depicting main processes of a MIS-type AlGaN/GaN-HEMT according to a modified example 2 in the second embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 13A and FIG. 13B, a gate insulating film 61 is formed.

More specifically, first, as depicted in FIG. 13A, similarly to the formation of the second insulating film 51b in FIG. 12B explained in the modified example 1, Al₂O₃ is deposited to have a film thickness of 15 nm or so by the ALD method so as to cover the entire surface on the compound semiconductor layer 2 including the top of a source electrode 4 and the top of a drain electrode 5. Thereby, a first insulating film 61a is formed.

Here, a SiC substrate 1 may also be subjected to a heat treatment.

Concretely, the SiC substrate 1 is heated for 5 minutes or so in a range of 400° C. to 1200° C., for example. Thereby, a bonding state of the first insulating film 61a is improved. By the advance introduction of the heat treatment, hydrogen termination collapse of the gate insulating film 61 is suppressed, and a state of a stable and low concentration corresponding to unpaired electrons is maintained. Further, Al₂O₃ in which the bonding state is improved by the heat treatment is employed, and thereby a gate withstand voltage is further stabilized.

Next, as depicted in FIG. 13B, similarly to the formation of the first insulating film 51a in FIG. 12A explained in the modified example 1, SiON is deposited on the first insulating film 61a to have a film thickness of 5 nm or so by the PECVD method. Thereby, a second insulating film 61b is formed. The second insulating film 61b is formed to have the same composition and property as those of the gate insulating film 41 in the second embodiment except that the film thickness is different.

Thus, the gate insulating film 61 in which the first insulating film 61a and the second insulating film 61b are sequentially layered is formed so as to cover the top of the compound semiconductor layer 2 including an internal surface of the electrode trench 2C.

The gate insulating film 61 includes the second insulating film 61b, so that dangling bonds are quite reduced and charge traps are significantly reduced. Further, the gate insulating film 61 includes the first insulating film 61a, so that the gate withstand voltage of the gate electrode is improved. That is, the application of the gate insulating film 61 makes it possible to achieve a significant reduction in charge trap density while achieving the high gate withstand voltage of the gate electrode.

Subsequently, as depicted in FIG. 13C, similarly to the second embodiment, a gate electrode 7 is formed through the process in FIG. 9B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 61 (particularly, charge traps on an interface of the gate insulating film 61 with the gate electrode 7 and in a vicinity region of the interface) are further significantly reduced and a change in electric properties is suppressed while achieving the high gate withstand voltage of the gate electrode 7.

### Modified Example 3

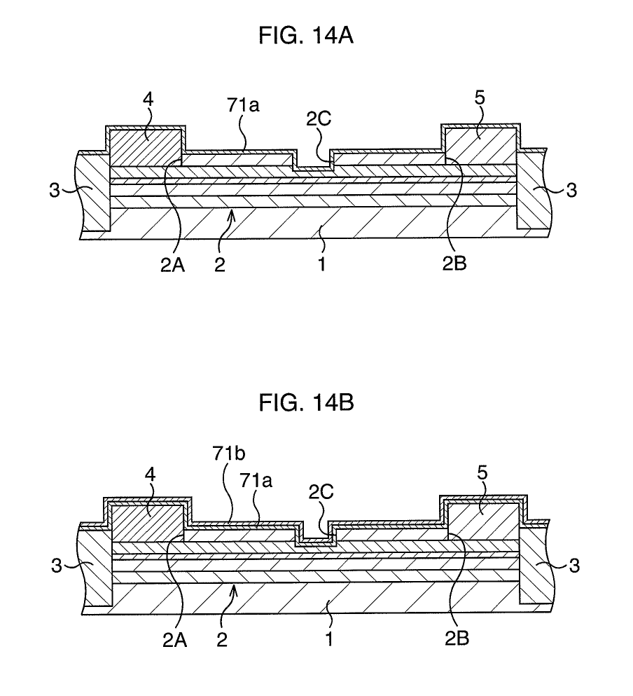

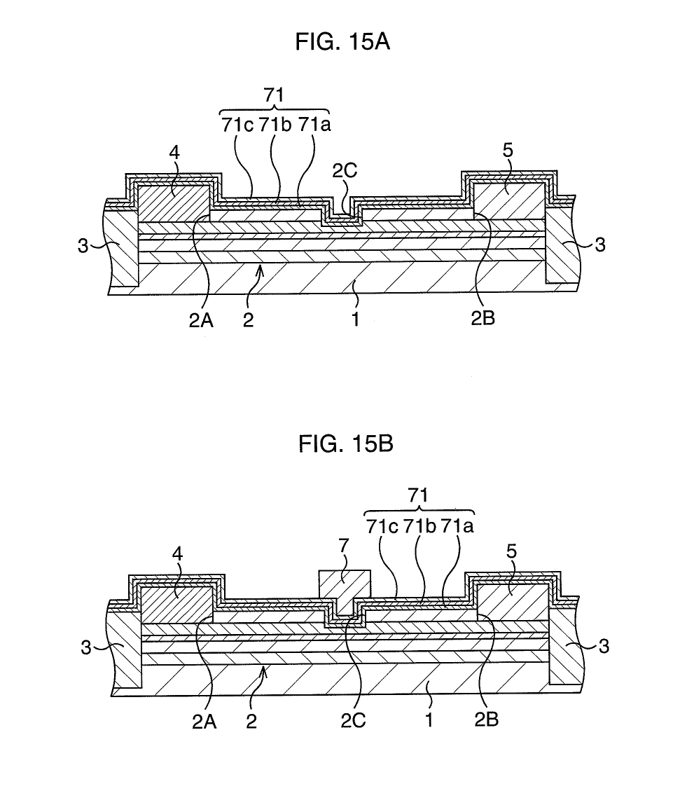

FIG. 14A and FIG. 14B and FIG. 15A and FIG. 15B are schematic cross-sectional views depicting main processes of a MIS-type AlGaN/GaN-HEMT according to a modified example 3 in the second embodiment.

First, similarly to the first embodiment, the MIS-type AlGaN/GaN-HEMT undergoes the various processes in FIG. 1A to FIG. 2B. An electrode trench 2C for a gate electrode is formed in a compound semiconductor layer 2.

Subsequently, as depicted in FIG. 14A, FIG. 14B, and FIG. 15A, a gate insulating film 71 is formed.

More specifically, first, as depicted in FIG. 14A, similarly to the formation of the first insulating film 51a in FIG. 12A explained in the modified example 1, SiON is deposited to have a film thickness of 5 nm or so by the PECVD method so as to cover the entire surface on the compound semiconductor layer 2 including the top of a source electrode 4 and the top of a drain electrode 5. Thereby, a first insulating film 71a is formed. The first insulating film 71a is formed to have the same composition and property as those of the gate insulating film 41 in the second embodiment except that the film thickness is different.

Next, as depicted in FIG. 14B, similarly to the formation of the second insulating film 51b in FIG. 12B explained in the modified example 1, Al₂O₃ is deposited on the first insulating film 71a to have a film thickness of 10 nm or so by the ALD method. Thereby, a second insulating film 71b is formed.

Next, as depicted in FIG. 15A, similarly to the formation of the first insulating film 71a, SiON is deposited on the second insulating film 71b to have a film thickness of 5 nm or so by the PECVD method. Thereby, a third insulating film 71c is formed.

Thus, the gate insulating film 71 in which the first insulating film 71a, the second insulating film 71b, and the third insulating film 71c are sequentially layered is formed so as to cover the top of the compound semiconductor layer 2 including an internal surface of the electrode trench 2C. The third insulating film 71c is formed to have the same composition and property as those of the gate insulating film 41 in the second embodiment except that the film thickness is different.

The gate insulating film 71 includes the first and third insulating films 71a, 71c, so that dangling bonds are quite reduced and charge traps are significantly reduced. Further, in the above case, the structure in which the second insulating film 71b is sandwiched between the first insulating film 71a and the third insulating film 71c is made, so that a state where dangling bonds on the front surface and rear surface of the gate insulating film 71 are quite reduced and charge traps are significantly reduced is made. Further, the gate insulating film 71 includes the second insulating film 71b, so that a gate withstand voltage of the gate electrode is improved. That is, the application of the gate insulating film 71 makes it possible to achieve a further significant reduction in charge trap density while achieving the high gate withstand voltage of the gate electrode.

Subsequently, as depicted in FIG. 15B, similarly to the first embodiment, a gate electrode 7 is formed through the process in FIG. 3B.

Thereafter, through various processes of forming a protective film, forming contacts of the source electrode 4, the drain electrode 5, and the gate electrode 7, and so on, the MIS-type AlGaN/GaN-HEMT is formed.

As explained above, according to this example, there is fabricated the highly-reliable AlGaN/GaN-HEMT in which charge traps in the gate insulating film 71 (particularly, charge traps on an interface of the gate insulating film 71 with the gate electrode 7 and in a vicinity region of the interface, or on an interface of the gate insulating film 71 with the compound semiconductor layer 2 and in a vicinity region of the interface) are further significantly reduced and a change in electric properties is suppressed while achieving the high gate withstand voltage of the gate electrode 7.

Incidentally, in the first and second embodiments, and their various modified examples, the SiC substrate 1 is used as a substrate, but the substrate is not limited to the SiC substrate 1. As long as a nitride semiconductor is used in a portion of the epitaxial structure having a function of a field-effect transistor, it does not matter even if another substrate made of sapphire, Si, GaAs, or the like is used. Further, as for the conductivity of the substrate, whether it is semi-insulating or conducting is not taken into consideration. Further, the layer structure of each of the source electrode 4, the drain electrode 5, and the gate electrode 7 in the first and second embodiments, and their various modified examples is one example, and it does not matter even if another layer structure is employed regardless of a single layer or a multilayer. Further, the method of forming each of the electrodes is also one example, and it does not matter even if any one of other forming methods is employed. Further, in the first and second embodiments, and their various modified examples, the heat treatment is performed at the time of forming the source electrode 4 and the drain electrode 5, but the heat treatment does not have to be performed as long as ohmic characteristics are obtained, and further, the heat treatment may also be further performed after the formation of the gate electrode 7. Further, in the first and second embodiments, and their various modified examples, the cap layer 2e is described as a single layer, but a cap layer composed of a plurality of compound semiconductor layers may also be employed. Further, in the first and second embodiments, and their modified examples, the electrode trench 2C in which the gate electrode 7 is formed is formed, but a structure without using the electrode trench 2C may also be made.

### Fourth Embodiment

In this embodiment, a power supply device provided with one type of the AlGaN/GaN-HEMTs selected from the first and second embodiments, and their various modified examples is disclosed.

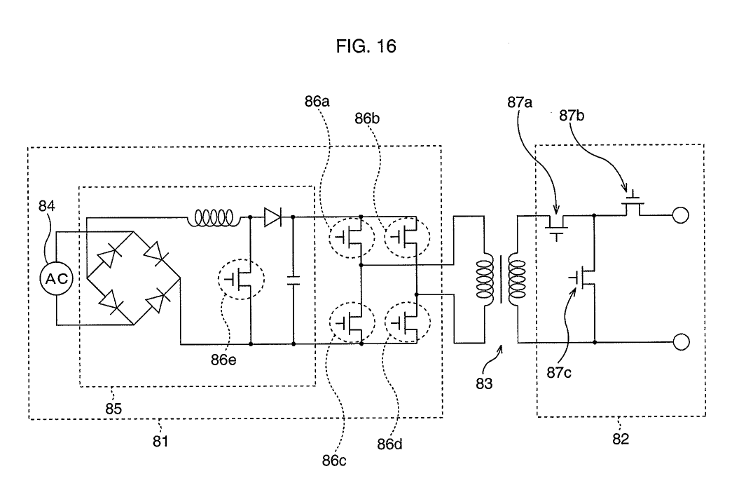

FIG. 16 is a connection diagram depicting a schematic structure of a power supply device according to a fourth embodiment.

The power supply device in this embodiment is structured to include: a high-voltage primary side circuit 81; a low-voltage secondary side circuit 82; and a transformer 83 provided between the primary side circuit 81 and the secondary side circuit 82.

The primary side circuit 81 is configured to include: an AC power supply 84; what is called a bridge rectifying circuit 85; and a plurality of (four, here) switching elements 86a, 86b, 86c, and 86d. Further, the bridge rectifying circuit 85 has a switching element 86e.

The secondary side circuit 82 is configured to include a plurality of (three, here) switching elements 87a, 87b, and 87c.

In this embodiment, each of the switching elements 86a, 86b, 86c, 86d, and 86e in the primary side circuit 81 is one type of the AlGaN/GaN-HEMTs selected from the first and second embodiments, and their various modified examples. On the other hand, each of the switching elements 87a, 87b, and 87c in the secondary side circuit 82 is a normal MIS-FET using silicon.

In this embodiment, there is applied the highly-reliable AlGaN/GaN-HEMT in which charge traps in the gate insulating film (particularly, charge traps on an interface of the gate insulating film with the gate electrode and in a vicinity region of the interface, or on an interface of the gate insulating film with the compound semiconductor layer 2 and in a vicinity region of the interface) are further significantly reduced and a change in electric properties is suppressed while achieving the high gate withstand voltage of the gate electrode to the high-voltage circuit. Thereby, the highly-reliable power supply device with high power is fabricated.

### Fifth Embodiment

In this embodiment, a high-frequency amplifier provided with one type of the AlGaN/GaN-HEMTs selected from the first and second embodiments, and their various modified examples is disclosed.

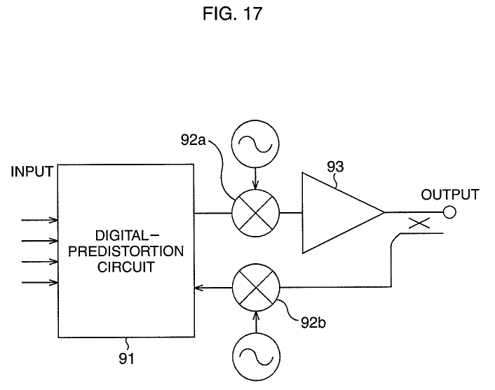

FIG. 17 is a connection diagram depicting a schematic structure of a high-frequency amplifier according to a fifth embodiment.

The high-frequency amplifier in this embodiment is structured to include: a digital-predistortion circuit 91; mixers 92a and 92b; and a power amplifier 93.

The digital-predistortion circuit 91 is to compensate nonlinear distortion of an input signal. The mixer 92a is to mix the input signal in which the nonlinear distortion is compensated and an AC signal. The power amplifier 93 is to amplify an input signal mixed with the AC signal, and has one type of the AlGaN/GaN-HEMTs selected from the first and second embodiments, and their various modified examples. Incidentally, in FIG. 17, the high-frequency amplifier is structured such that by switching a switch, for example, a signal on an output side is mixed with an AC signal in the mixer 92b and the mixed signal is allowed to be transmitted to the digital-predistortion circuit 91.

In this embodiment, there is applied the highly-reliable AlGaN/GaN-HEMT in which charge traps in the gate insulating film (particularly, charge traps on an interface of the gate insulating film with the gate electrode and in a vicinity region of the interface, or on an interface of the gate insulating film with the compound semiconductor layer 2 and in a vicinity region of the interface) are further significantly reduced and a change in electric properties is suppressed while achieving the high gate withstand voltage of the gate electrode to the high-frequency amplifier. Thereby, the highly-reliable high-frequency amplifier with a high withstand voltage is fabricated.

### Other Embodiments

In the first to fifth embodiments, and the various modified examples, as the compound semiconductor device, the AlGaN/GaN-HEMT is described as an example. As the compound semiconductor device, HEMTs as below can be employed other than the AlGaN/GaN-HEMT.

### Another HEMT Example 1

In this example, as the compound semiconductor device, an InAlN/GaN-HEMT is disclosed.

InAlN and GaN are compound semiconductors in which their lattice constants are allowed to be close to each other according to their compositions. In the above case, in the above-described first to fifth embodiments and various modified examples, the electron transit layer is formed of i-GaN, the intermediate layer is formed of i-InAlN, the electron supply layer is formed of n-InAlN, and the cap layer is formed of n-GaN. Further, in the above case, piezoelectric polarization hardly occurs, so that a two-dimensional electron gas mainly occurs by spontaneous polarization of InAlN.

According to this example, similarly to the above-described AlGaN/GaN-HEMT, there is fabricated the highly-reliable InAlN/GaN-HEMT in which charge traps in the gate insulating film (particularly, charge traps on an interface of the gate insulating film with the gate electrode and in a vicinity region of the interface, or on an interface of the gate insulating film with the compound semiconductor layer 2 and in a vicinity region of the interface) are further significantly reduced and a change in electric properties is suppressed while achieving the high gate withstand voltage of the gate electrode.

### Another HEMT Example 2

In this example, as the compound semiconductor device, an InAlGaN/GaN-HEMT is disclosed.

GaN and InAlGaN are compound semiconductors, in which a lattice constant of the latter compound semiconductor is smaller than that of the former compound semiconductor. In the above case, in the above-described first to fifth embodiments and various modified examples, the electron transit layer is formed of i-GaN, the intermediate layer is formed of i-InAlGaN, the electron supply layer is formed of n-InAlGaN, and the cap layer is formed of n⁺-GaN.

According to this example, similarly to the above-described AlGaN/GaN-HEMT, there is fabricated the highly-reliable InAlGaN/GaN-HEMT in which charge traps in the gate insulating film (particularly, charge traps on an interface of the gate insulating film with the gate electrode and in a vicinity region of the interface, or on an interface of the gate insulating film with the compound semiconductor layer 2 and in a vicinity region of the interface) are further significantly reduced and a change in electric properties is suppressed while achieving the high gate withstand voltage of the gate electrode.

According to the above-described respective aspects, the highly-reliable compound semiconductor device in which charge traps in the gate insulating film are significantly reduced and a change in electric properties is suppressed is fabricated.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has(have) been described in detail, it should be understood that the various changes, substitutions, and alterations could be made hereto without departing from the spirit and scope of the invention.

What is claimed is:

1. A compound semiconductor device, comprising:
a compound semiconductor layer; and
a gate electrode formed on the compound semiconductor layer via a gate insulating film, wherein
the gate insulating film is one in which SiₓN_{y} is contained as an insulating material,
the SiₓN_{y} is 0.638≦x/y≦0.863, and a hydrogen-terminated group concentration is set to a value within a range of not less than 2×10²²/cm³ nor more than 5×10²²/cm³.

2. A compound semiconductor device, comprising:
a compound semiconductor layer; and
a gate electrode formed on the compound semiconductor layer via a gate insulating film, wherein
the gate insulating film is one in which SiₓO_{y}N_{z} is contained as an insulating material,
the SiₓO_{y}N_{z} satisfies
x:y:z=0.256 to 0.384:0.240 to 0.360:0.304 to 0.456 and x+y+z=1, and
a hydrogen-terminated group concentration is set to a value within a range of not less than 2×10²²/cm³ nor more than 5×10²²/cm³.

3. The compound semiconductor device according to claim 1, wherein
the gate insulating film is one in which an interatomic hydrogen concentration of the insulating material is not less than 2×10²¹/cm³ nor more than 6×10²¹/cm³.

4. The compound semiconductor device according to claim 1, wherein
the gate insulating film comprises a layered structure of
a first insulating film formed of the insulating material; and
a second insulating film made of a material having a band gap larger than that of the insulating material.

5. The compound semiconductor device according to claim 4, wherein
the second insulating film is thicker than the first insulating film.

6. The compound semiconductor device according to claim 4, wherein
the gate insulating film is formed by layering the second insulating film on the first insulating film.

7. The compound semiconductor device according to claim 4, wherein
the gate insulating film is formed by layering the first insulating film on the second insulating film.

8. The compound semiconductor device according to claim 4, wherein
the second insulating film comprises at least one type selected from Al₂O₃, AlN, and TaO.

9. The compound semiconductor device according to claim 1, wherein
the gate insulating film comprises a layered structure of a first insulating film formed of the insulating material,
a second insulating film made of a material having a band gap larger than that of the insulating material, and
a third insulating film formed of the insulating material.

10. A method of manufacturing a compound semiconductor device, comprising:
forming a gate insulating film on a compound semiconductor layer; and
forming a gate electrode on the compound semiconductor layer via the gate insulating film, wherein
the gate insulating film is one in which SiₓN_{y} is contained as an insulating material,
the SiₓN_{y} is 0.638≦x/y≦0.863, and a hydrogen-terminated group concentration is set to a value within a range of not less than 2×10²²/cm³ nor more than 5×10²²/cm³.

11. A method of manufacturing a compound semiconductor device, comprising:
forming a gate insulating film on a compound semiconductor layer; and
forming a gate electrode on the compound semiconductor layer via the gate insulating film, wherein
the gate insulating film is one in which SiₓO_{y}N_{z} is contained as an insulating material,
the SiₓO_{y}N, satisfies
x:y:z=0.256 to 0.384:0.240 to 0.360:0.304 to 0.456 and x+y+z=1, and
a hydrogen-terminated group concentration is set to a value within a range of not less than 2×10²²/cm³ nor more than 5×10²²/cm³.

12. The method of manufacturing the compound semiconductor device according to claim 10, wherein
the insulating material is deposited by a plasma CVD method to set RF power to a value within a range of not less than 20 W nor more than 200 W.

13. The method of manufacturing the compound semiconductor device according to claim 10, wherein
the gate insulating film is one in which an interatomic hydrogen concentration of the insulating material is not less than 2×10²¹/cm³ nor more than 6×10²¹/cm³.

14. The method of manufacturing the compound semiconductor device according to claim 10, wherein
the gate insulating film comprises a layered structure of
a first insulating film formed of the insulating material; and
a second insulating film made of a material having a band gap larger than that of the insulating material.

15. The method of manufacturing the compound semiconductor device according to claim 14, wherein
the second insulating film is thicker than the first insulating film.

16. The method of manufacturing the compound semiconductor device according to claim 14, wherein
the gate insulating film is formed by layering the second insulating film on the first insulating film.

17. The method of manufacturing the compound semiconductor device according to claim 14, wherein
the gate insulating film is formed by layering the first insulating film on the second insulating film.

18. The method of manufacturing the compound semiconductor device according to claim 14, wherein
the second insulating film comprises at least one type selected from Al₂O₃, AlN, and TaO.

19. A power supply device, comprising:
a transformer; and
a high-voltage circuit and a low-voltage circuit between which the transformer is interposed, wherein
the high-voltage circuit comprises a transistor,
the transistor comprises:
a compound semiconductor layer; and
a gate electrode formed on the compound semiconductor layer via a gate insulating film, and
the gate insulating film is one in which SiₓN_{y} or SiₓO_{y}N_{z} is contained as a material,
the SiₓN_{y} is 0.638≦x/y≦0.863,
or, the SiₓO_{y}N_{z} is x:y:z=0.256 to 0.384:0.240 to 0.360:0.304 to 0.456, and is x+y+z=1, and
a hydrogen-terminated group concentration of the SiₓN_{y} or the SiₓO_{y}N_{z} is set to a value within a range of not less than 2×10²²/cm³ nor more than 5×10²²/cm³.

20. A high-frequency amplifier being a high-frequency amplifier amplifying an input high-frequency voltage to output an amplified voltage, the high-frequency amplifier comprising:
a transistor, wherein
the transistor comprises:
a compound semiconductor layer; and
a gate electrode formed on the compound semiconductor layer via a gate insulating film, and
the gate insulating film is one in which SiₓN_{y} or SiₓO_{y}N_{z} is contained as a material,
the SiₓN_{y} is 0.638≦x/y≦0.863,
or, the SiₓO_{y}N_{z} is x:y:z=0.256 to 0.384:0.240 to 0.360:0.304 to 0.456, and is x+y+z=1, and
a hydrogen-terminated group concentration of the SiₓN_{y} or the SiₓO_{y}N_{z} is set to a value within a range of not less than 2×10²²/cm³ nor more than 5×10²²/cm³.
